(19) United States
(12) Patent Application Publication
(10) Pub. No.: US 2025/0189462 A1
(43) Pub. Date: Jun. 12, 2025

(54) INSPECTION FLOW DETERMINATION DEVICE, CHARGED PARTICLE BEAM DEVICE, AND PROGRAM

(71) Applicant: HItachi High-Tech Corporation, Tokyo (JP)

(72) Inventors: Norifumi KAMESHIRO, Tokyo (JP); Kazuo Ono, Tokyo (JP); Shota Mitsugi, Tokyo (JP); Satoshi Takada, Tokyo (JP); Ritsuo Fukaya, Tokyo (JP); HIroki Watanabe, Tokyo (JP); Shinya Sakita, Tokyo (JP)

(21) Appl. No.: 18/977,164

(22) Filed: Dec. 11, 2024

(30) Foreign Application Priority Data
Dec. 12, 2023 (JP) 2023-208927

(51) Int. Cl. G01N 23/04; H01J 37/28

(52) U.S. Cl. CPC G01N 23/04; H01J 37/28; G01N 2223/102; H01J 2237/24592

(57) ABSTRACT

An inspection flow determination device including an inspection time estimation unit configured to estimate an inspection time required to inspect an inspection point extracted under a predetermined condition based on grouping data in which inspection points of a wafer are grouped to belong to at least one field of view (FOV); and an inspection data extraction unit configured to extract an inspection point using the condition selected based on the estimated inspection time as an extraction condition. The inspection time estimation unit extracts an inspection point from the grouping data based on an FOV selection rule for determining whether to perform or skip FOV movement using the number of times of FOV movement as a parameter, and an inspection point selection rule for determining whether to inspect or skip an inspection point using the number of inspection points to be actually inspected in the FOV as a parameter.

### CROSS-REFERENCE TO RELATED APPLICATION

This application claims priority to Japanese Patent Application No. 2023-208927 filed on Dec. 12, 2023, the entire contents of which are incorporated by reference herein.

### TECHNICAL FIELD

The present invention relates to an inspection flow determination device, a charged particle beam device, and a program.

### BACKGROUND ART

When a device or a wiring is formed on a semiconductor wafer (hereinafter, referred to as a “wafer”), a method is adopted in which a film of a semiconductor, a conductor, or an insulator is formed on the wafer, a mask pattern of a photomask is transferred to a photosensitive resist by photolithography, and the film is etched using the resist as an etching mask. In these steps, a length measurement scanning electron microscope (SEM) is widely used for evaluating a dimension of transfer of the mask pattern and a finished dimension after etching.

The SEM can also evaluate not only a dimension and a shape but also an electric characteristic of a sample. For example, a voltage contrast image can be formed based on detection of secondary electrons or the like obtained by irradiating the sample with an electron beam, and an electric characteristic of an element formed on the sample can be evaluated based on analysis of the voltage contrast image. In addition, it is also possible to evaluate a resistance value based on a steady charge amount accompanying electron beam irradiation, and evaluate a capacitance characteristic based on a transient response characteristic of the charge amount.

In the evaluation by the SEM, any inspection point moves so as to enter a field of view (FOV) by stage movement, and a dimension, shape data, or an electric characteristic of an inspection pattern is acquired to evaluate a performance. Therefore, an inspection time required for the evaluation by the SEM is a sum of a movement time to the FOV and a measurement time of each inspection point in the FOV.

With higher integration of semiconductors in recent years, the number of inspection points in an evaluation step significantly increases. Therefore, a method of automatically creating, based on CAD data, a recipe for specifying a position, a magnification, an image quality, or the like required for an evaluation is the mainstream. In addition, in the recipe creation, there is also known a technique for determining a position at which the FOV is to be disposed, which includes not only extraction of a position of an inspection point but also a correspondence relationship between the inspection point and the FOV in which the inspection point is inspected (see PTLs 1 and 2).

### CITATION LIST

### Patent Literature

PTL 1: JP2010-276382A
PTL 2: U.S. patent application Ser. No. 10/515,444

### SUMMARY OF INVENTION

### Technical Problem

In the case of evaluating a wide range, such as the entire surface of a wafer, using an SEM for a large number of inspection points which become finer along with higher integration of the semiconductors, since the measurement of each inspection point is performed while moving an FOV in a very small range as compared with an optical inspection device, a throughput of the inspection is a bottle neck. In response to an increase in the number of inspection points, even though an operation time of recipe creation can be shortened by automation of the recipe creation, a problem that the time required for inspection is too long is not solved. In addition, in order to prevent an increase in the inspection time, inspection coordinate data in which the inspection point is extracted such that the inspection is completed within a specified time may be created. However, there is no known technique for creating data adjusted to a desired number of inspection points or the number of times of FOV movement in consideration of a relationship between the inspection point and the FOV in which the inspection point is inspected.

### Solution to Problem

An inspection flow determination device according to an embodiment of the invention includes: an inspection time estimation unit configured to estimate an inspection time required to inspect an inspection point extracted under a predetermined condition based on grouping data in which inspection points of a wafer to be inspected are grouped to belong to at least one field of view (FOV); and an inspection data extraction unit configured to extract an inspection point, which is extracted using the condition selected based on the inspection time estimated by the inspection time estimation unit as an extraction condition, as an inspection point of inspection data indicating an inspection point where the wafer is actually inspected. The inspection time estimation unit extracts an inspection point from the grouping data based on an FOV selection rule for determining whether to perform or skip FOV movement using the number of times of FOV movement as a first parameter, and an inspection point selection rule for determining whether to actually inspect or skip an inspection point using the number of inspection points to be actually inspected in the FOV as a second parameter.

### Advantageous Effects of Invention

Inspection data adjusted to a desired number of inspection points and the number of times of FOV movement can be created within a specified inspection time. Other problems and novel features will become apparent from description of the present specification and the accompanying drawings.

### BRIEF DESCRIPTION OF DRAWINGS

FIG. 1 is a schematic configuration diagram of a charged particle beam device.

FIG. 2 is a hardware structure example of an information processing device.

FIG. 3 is a functional block diagram of a control device that determines an inspection flow of a wafer and executes an inspection by the charged particle beam device according to Embodiment 1.

FIG. 4 is an example of a rule setting screen.

FIG. 5A is a diagram showing an example of an FOV selection rule.

FIG. 5B is a diagram showing an example of an inspection point selection rule.

FIG. 6A is a display example of extraction condition setting support information.

FIG. 6B is another display example of the extraction condition setting support information shown in FIG. 6A.

FIG. 7A is a display example of another extraction condition setting support information.

FIG. 7B is a display example of another extraction condition setting support information.

FIG. 8A is an example of an extraction condition selection screen.

FIG. 8B is an example of the extraction condition selection screen.

FIG. 9A is an example of the extraction condition selection screen.

FIG. 9B is an example of the extraction condition selection screen.

FIG. 10 is a diagram schematically showing an inspection sequence according to Embodiment 2.

FIG. 11 is a functional block diagram of a control device that determines an inspection flow of a wafer and executes an inspection by a charged particle beam device according to Embodiment 2.

FIG. 12 is a functional block diagram of a control device that determines an inspection flow of a wafer and executes an inspection by a charged particle beam device according to Embodiment 3.

FIG. 13 is a diagram showing a method of creating grouping data.

FIG. 14A is a data structure example of the grouping data.

FIG. 14B is an arrangement example of inspection points indicated by the grouping data in FIG. 14A.

### DESCRIPTION OF EMBODIMENTS

Hereinafter, embodiments of the invention will be described with reference to the drawings. Aspects described in the embodiment are examples for implementing the invention, and do not limit the technical scope of the invention. For example, the embodiments described below have been described in detail in order to describe the invention in an easy-to-understand manner, and are not necessarily limited to including all the described configurations. In addition, a part of a configuration in one embodiment can be replaced with a configuration in another embodiment, and a configuration in one embodiment can also be added to a configuration in another embodiment. In addition, a part of a configuration in each embodiment may be added to, deleted from, or replaced with another configuration. In the embodiment, members having the same function are denoted by the same reference signs, and the repeated description thereof is omitted unless particularly necessary. In addition, the related art portion not directly related to the invention is omitted.

When there are a plurality of components having the same or similar functions, the description may be made by assigning the same reference signs thereof with different subscripts. However, when it is not necessary to distinguish the plurality of components from each other, the description may be made by omitting the subscripts.

The notations “first”, “second”, “third”, or the like in the present specification or the like are provided to identify the components, and do not necessarily limit the number, the order, or the content thereof. In addition, a number for identifying a component is used for each context, and the number used in one context does not necessarily indicate the same configuration in another context. In addition, this does not prevent a component identified by a certain number from also having a function of a component identified by another number.

In order to facilitate understanding of the invention, the position, size, shape, range, or the like of each configuration shown in the drawings or the like may not represent the actual position, size, shape, range, or the like. Therefore, the invention is not necessarily limited to the position, size, shape, range, or the like disclosed in the drawings.

Publications, patents, and patent applications cited in the present specification constitute a part of the description of the present specification.

In the present specification, a component represented in a single form includes a plurality of forms unless otherwise clearly described in the context.

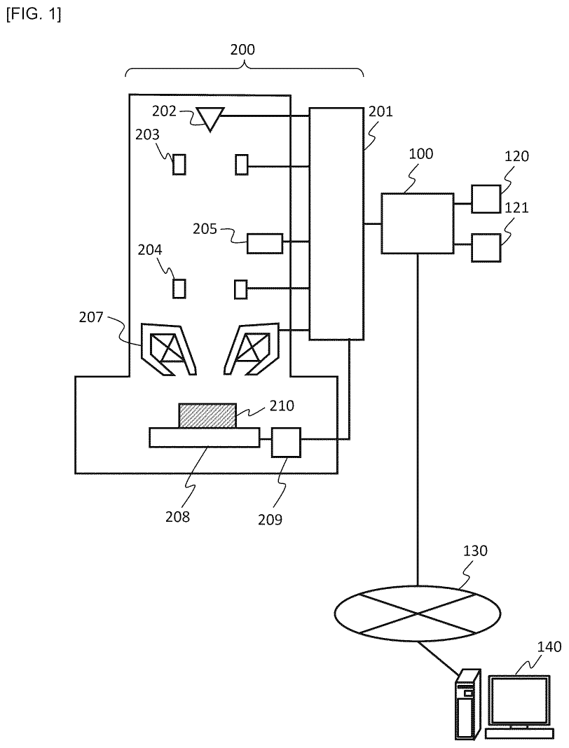

FIG. 1 is a schematic configuration diagram of a charged particle beam device. Here, an electron microscope using an electron beam as a charged particle beam is taken as an example. An ion microscope or the like that uses an ion beam as a charged particle beam may also be used. The charged particle beam device includes an electron microscope body 200 and a control device 100. An input device 120 and a display device 121 serving as an interface for a user to operate the electron microscope body are connected to the control device 100.

The electron microscope body 200 mainly includes a charged particle optical system (here, an electron optical system), a stage mechanism system, and a controller group 201.

The electron optical system mainly includes an electron source 202, a blanker 203 that pulses an electron beam from the electron source 202, a deflector 204 that controls an irradiation position of the electron beam on a sample 210, an electron lens 207 that focuses the electron beam on the sample 210, and a detector 205 that detects a signal electron emitted from the sample (wafer) 210 irradiated with the electron beam. The stage mechanism system includes a sample stage 208 on which the sample 210 to be inspected is placed and a stage mechanism 209 that drives the sample stage 208. The electron optical system and the stage mechanism system are provided in a vacuum environment. Although not shown in FIG. 1, an irradiation optical system for controlling a sample potential of the sample 210 may be provided when an electric characteristic of an element is inspected. In order to control the charging of the sample 210, the irradiation optical system includes, for example, a laser light source for emitting laser light and an optical system for controlling an irradiation point thereof.

The electron optical system and the stage mechanism system are controlled by the controller group 201 that controls components thereof. For example, the control device 100 outputs a control signal to the controller group 201 according to a program for the electron microscope body 200 to execute an inspection, and executes the inspection of the sample 210 by the controller group 201 controlling each component according to the control signal. The control device 100 is connected to a wafer inspection management device 140 via a network 130. The wafer inspection management device 140 provides inspection information of the wafer 210 to be inspected to the control device 100.

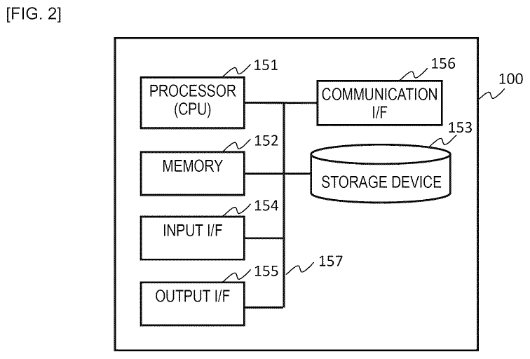

The control device 100 is implemented by an information processing device (computer) mainly including a processor (central processing unit: CPU) 151, a memory 152, a storage device 153, an input interface (I/F) 154, an output I/F 155, a communication I/F 156, and a bus 157 as shown in FIG. 2. The processor 151 functions as a functional unit that provides a predetermined function by executing processing according to a program loaded in the memory 152. The storage device 153 stores data and a program used by the functional unit. The input I/F 154 is connected to the input device 120 such as a keyboard, a pointing device, or an operation panel, and the output I/F 155 is connected to the display device 121. The communication device I/F 156 enables communication with another information processing device, for example, the wafer inspection management device 140 via the network 130. These components are communicably connected to one another via the bus 157.

In the follow description, in the case of describing processing executed by a program, a program, a functional unit, or the like may be described as a main body, but a main body of hardware thereof is a processor, or an information processing device (computer) that includes the processor or the like. The information processing device executes processing according to a program read onto a memory by a processor while appropriately using resources such as a memory and a communication interface. Although FIG. 2 shows an example of a CPU as a processor, a graphical processing unit (GPU) or the like may also be used. Processing for implementing a function is not limited to software program processing, and can be implemented by a dedicated circuit. As the dedicated circuit, a field programmable gate array (FPGA), an application specific integrated circuit (ASIC), or the like can be applied.

### Embodiment 1

The control device 100 has a function of receiving inspection information of a wafer to be inspected from the wafer inspection management device 140 and determining an inspection flow of the wafer.

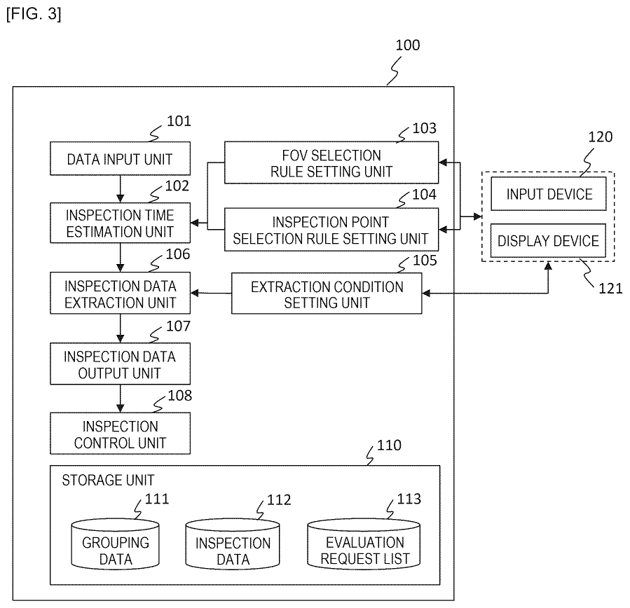

FIG. 3 is a functional block diagram of the control device 100 that determines the inspection flow of the wafer and executes an inspection by the charged particle beam device. A storage unit 110 stores grouping data 111 created by the wafer inspection management device 140 and transmitted to the control device 100. The grouping data 111 is data obtained by grouping inspection points on the wafer to belong to at least one FOV. When the grouping data 111 is input to a data input unit 101, an inspection time estimation unit 102 estimates, based on the input grouping data 111, a time required for the inspection of the wafer (hereinafter referred to as an “inspection time”) using the number of times of FOV movement and the number of inspection points as parameters. At this time, the number of times of FOV movement (first parameter) and the number of inspection points (second parameter) to be actually inspected in the FOV, which are parameters for estimating the inspection time, are used for a first rule (hereinafter referred to as an “FOV selection rule”) for determining whether to perform or skip FOV movement, and a second rule (hereinafter referred to as an “inspection point selection rule”) for determining whether to perform or skip an inspection of each inspection point in the FOV. For the FOV selected by the first rule, the inspection time estimation unit 102 further extracts, by selecting inspection points based on the second rule, the inspection points to be actually inspected, and estimates the inspection time in that case. A detailed setting of the FOV selection rule is performed by an FOV selection rule setting unit 103, and a detailed setting of the inspection point selection rule is performed by an inspection point selection rule setting unit 104.

Based on the inspection time estimated by the inspection time estimation unit 102, an extraction condition setting unit 105 sets a condition for extracting desired inspection coordinate data. An inspection data extraction unit 106 extracts data of an inspection point for executing an inspection based on the extraction condition set by the extraction condition setting unit 105, and stores the extracted data in the storage unit 110 as inspection data 112. As described above, the inspection data 112 is created, based on the grouping data 111 having a relationship between an inspection point of the wafer and the FOV in which the inspection point is inspected, as a list of inspection points in which the number of times of FOV movement and the number of inspection points are adjusted such that the inspection of the wafer is completed within a specified time.

An inspection control unit 108 controls the stage mechanism 209 according to the inspection data 112 stored in the storage unit 110 to move (stage movement) the sample stage 208 on which the sample (wafer) 210 formed with a pattern is placed, and finely adjusts (image shift) a position of the FOV by controlling the deflector 204. At this time, the FOV may be displayed on the display device 121, and the user may confirm the FOV. In a state where the FOV to be inspected is defined, the inspection control unit 108 sequentially inspects each inspection point in the FOV. When the inspections of the inspection points in the FOV are completed, the inspection control unit 108 moves the sample stage 208 to the next FOV. By executing the inspections for all the inspection points listed in the inspection data 112 in a series of flows, the inspections are completed. The inspection of the inspection point may be dimension measurement of a pattern of the inspection point, or may be an evaluation of an electric characteristic of the pattern of the inspection point.

Here, an example is described in which the control device 100 creates the inspection data 112 from the grouping data 111. The inspection data 112 may be created in another information processing device, for example, the wafer inspection management device 140, and the inspection data 112 may be transmitted to the control device 100. A device that creates the inspection data 112, that is, executes the functional blocks 101 to 107 that determine the inspection flow may be referred to as an inspection flow determination device. Hereinafter, the processing performed by the inspection flow determination device will be described in detail.

### (Inspection Time Estimation Unit 102)

The inspection time estimation unit 102 estimates the inspection time using the number of times of FOV movement and the number of inspection points to be actually inspected in the FOV as parameters. A formula for estimating the inspection time is, for example, (Formula 1).

$$[ Formula 1 ]$$

$$T = {\sum }_{m = 1}^{{num}_{FOV}} {x}_{m} * \{ {t}_{SM} + {t}_{IS} + {t}_{IT} * {ratio}_{IT} * {z}_{m} \} \qquad ( 1 )$$

Here, T is a total inspection time, t_{SM}, t_{IS}, and t_{IT} are an average time taken for the stage movement by the stage mechanism 209, an average time taken for the image shift by the deflector 204, and an average time taken for the measurement of the inspection points, respectively. In addition, num_{FOV} is a total number of FOVs defined in the grouping data 111. xₘ is a binary variable that becomes 1 or 0 depending on whether the m-th FOV movement (stage movement and image shift) is performed or skipped, zₘ is the number of inspection points included in the m-th FOV, and ratio_{IT} is a ratio of the number of inspection points to be actually inspected to the number of inspection points included in the FOV.

Here, when (Formula 1) is modified using (Formula 2), (Formula 3) is obtained.

$$[ Formula 2 ]$$

$$\{ \begin{matrix}{ratio}_{FOV} = \frac{{\sum }_{m = 1}^{{num}_{FOV}} {x}_{m}}{{num}_{FOV}} \\ {num}_{IT} = {\sum }_{m = 1}^{{num}_{FOV}} {x}_{m} * {z}_{m}\end{matrix} \qquad ( 2 )$$

Here, the ratio_{FOV} is an FOV movement ratio obtained by dividing the number of FOVs selected by performing FOV movement by the total number of FOVs num_{FOV}. In addition, num_{IT} is the total number of inspection points included in the FOV selected by performing FOV movement.

$$[ Formula 3 ]$$

$$T = \{ ( {t}_{SM} + {t}_{IS} ) * {ratio}_{FOV} * {num}_{FOV} \} + ( {t}_{IT} * {ratio}_{IT} * {num}_{IT} ) \qquad ( 3 )$$

Here, t_{SM}, t_{IS}, and t_{IT} are values unique to the charged particle beam device to be inspected. (Formula 3) indicates that the total inspection time T is merely determined by the FOV movement ratio ratio_{FOV} and the inspection point number ratio ratio_{IT} even when the FOV for performing the FOV movement and the inspection points to be actually inspected in the FOV are selected on any basis. Therefore, the FOV selection rule and the inspection point selection rule for creating desired inspection coordinate data can be set without affecting the inspection time calculated by the inspection time estimation unit 102. (FOV Selection Rule Setting Unit 103 and Inspection Point Selection Rule Setting Unit 104)

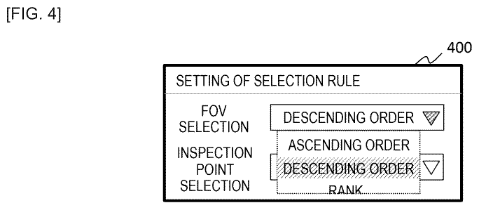

FIG. 4 is an example of a rule setting screen displayed on the display device 121 by the FOV selection rule setting unit 103 and the inspection point selection rule setting unit 104. The FOV selection rule and the inspection point selection rule can be set in an inspection flow determination program or in a setting file for storing various measurement condition settings. A configuration in which the user can set a desired extraction condition is preferable. Here, on a selection rule setting screen 400 displayed on the display device 121, the desired conditions can be selected for the FOV selection rule and the inspection point selection rule, and the selection rule selected here is set in the FOV selection rule setting unit 103 and the inspection point selection rule setting unit 104.

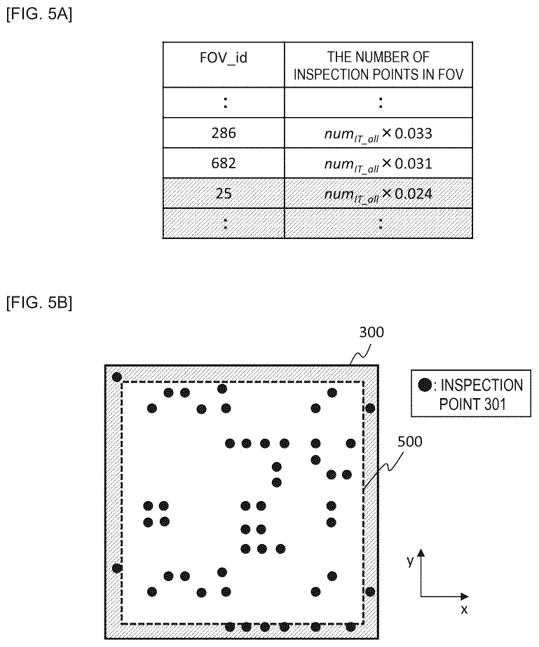

FIG. 5A is a schematic diagram showing an example of a rule for selecting whether to perform or skip movement to the FOV defined in the grouping data 111 in the FOV selection rule setting. In this example, the FOVs are rearranged in descending order according to the number of inspection points in the FOVs, and it is determined whether to perform or skip the FOV movement based on a set threshold. FOV_id is an ID for uniquely identifying an FOV, and num_{IT _all} is the total number of inspection points defined in the grouping data 111. Here, the number of inspection points belonging to the FOV is represented by a product of the total number of inspection points num_{IT _all} and a ratio of the number of inspection points to the total number of inspection points num_{IT_all}. For example, when an FOV movement ratio ratio_{FOV} is set to 0.8, the total number of FOVs num_{FOV}×0.8-th FOV from above in the FOVs arranged in descending order of the number of inspection points in the FOV is FOV_id: 682. In this case, the FOV movement is performed on an FOV in which the number of inspection points in the FOV is equal to or larger than the number of inspection points in FOV_id: 682, and it is determined that the FOV less than the number of inspection points in FOV_id: 682 is skipped.

The FOV selection rule is not limited to the above description, and may be rearranged in ascending order. In addition, a method is conceivable that FOVs are divided into a plurality of ranks according to the number of inspection points defined in the grouping data 111, and a constant ratio of FOVs in each rank is randomly skipped, or FOVs in which FOV movement is simply and randomly performed is selected.

On the other hand, FIG. 5B is a schematic diagram showing an example of a rule for selecting whether to perform or skip an inspection of an inspection point defined in the grouping data 111 in the FOV in the setting of the inspection point selection rule. A plurality of inspection points 301 are provided inside an FOV 300. In this example, an inspection point distance is calculated to be one of a distance in an x-coordinate direction and a distance in a y-coordinate direction from an FOV center position. The inspection points are arranged in ascending order according to the inspection point distance, and it is determined whether to perform or skip an inspection based on the set threshold value. For example, when an inspection point number ratio ratio_{IT} is set to 0.8, it is determined to perform inspections on inspection points up to zₘ×0.8-th of the number of inspection points in the FOV whose x coordinate or y coordinate is closer to the FOV center position (the inspection points 301 located inside an inspection boundary 500), and skip the other inspection points (the inspection points 301 located outside the inspection boundary 500).

The inspection point selection rule is not limited to the above description, and a method is conceivable that inspection points in any position (for example, an upper half region or a right lower region) in the FOV are skipped and an inspection point is simply and randomly selected in the FOV.

### (Extraction Condition Setting Unit 105)

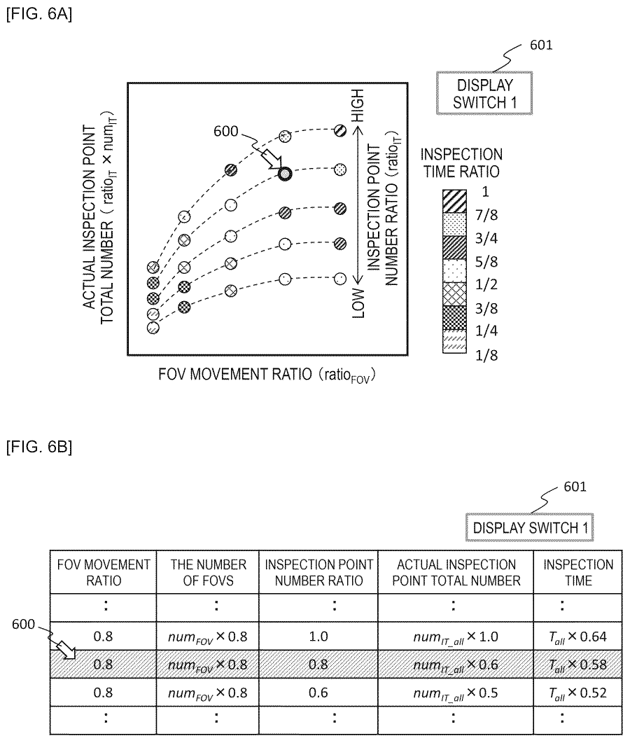

FIG. 6A is an example of information that is displayed on the display device 121 by the extraction condition setting unit 105 and supports the user to set the extraction condition. As support information, the total number of inspection points to be actually inspected (referred to as actual inspection point total number ratio_{IT}×num_{IT}), which is extracted by changing first information (FOV movement ratio ratio_{FOV}) based on the number of times of FOV movement and second information (inspection point number ratio ratio_{IT}) based on the number of inspection points, on the inspection points defined in the grouping data 111 is shown as a graph. Markers of the graph correspond to extraction conditions for extracting the inspection points to be actually inspected from the inspection points defined in the grouping data 111. Further, a label of the marker displays an inspection time ratio. Here, the inspection time ratio is a ratio of a total inspection time T required for inspecting an inspection point extracted under a predetermined condition to a total inspection time Tₐₗₗ required to inspect all the inspection points defined in the grouping data 111.

The support information shown in FIG. 6A means that even when the actual inspection point total number ratio_{IT}×num_{IT} is the same, there are extraction conditions in which the number of FOVs or the number of times of FOV movement, the number of inspection points, and the inspection time are different. The user can select an extraction condition as a desired inspection condition from the first information, the second information, and third information (inspection time ratio) based on the inspection time. A display method of the support information is not limited to the one shown in the drawing. The first information, the second information, and the third information may be the number of FOVs or the number of times of FOV movement, the number of inspection points to be actually inspected in the FOV, and the inspection time, respectively. Three pieces of information represented by two axes and the label of the marker may be interchanged, or may be represented by a three-dimensional graph. The label of the marker may be subdivided or displayed with a smooth color change.

FIG. 6B is an example of another display method of the support information shown in FIG. 6A. By displaying a list in this manner, detailed numerical data can be confirmed. A display switch button 601 may switch the display of FIGS. 6A and 6B. The user can select a desired extraction condition by a pointer 600 on the screen shown in FIG. 6A or FIG. 6B.

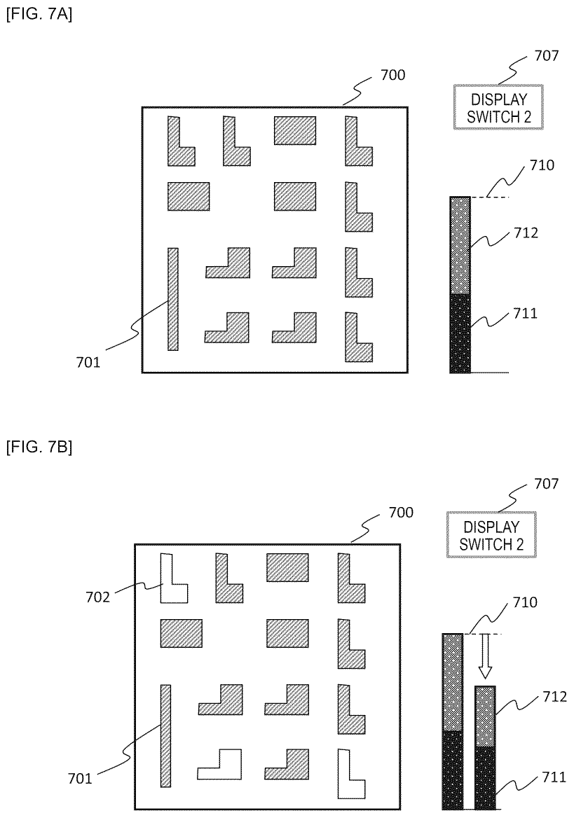

FIGS. 7A and B are another example of the information that is displayed on the display device 121 by the extraction condition setting unit 105 and supports the user to set the extraction condition. A chip pattern is repeatedly formed on the wafer to be inspected. In this example, a layout diagram schematically showing an inspected pattern 701 corresponding to an inspection point on a chip pattern 700 is displayed. FIG. 7A shows a state where all the inspected patterns 701 on the chip pattern 700 are inspection targets. That is, it corresponds to a case where all the inspection points defined in the grouping data 111 are inspected. In addition to the layout diagram, an inspection time estimation 710 is shown. Here, the inspection time estimation 710 is indicated by a sum of an FOV movement time 711 (corresponding to a first term on the right side of (Formula 3)) and an inspection point measurement time 712 (corresponding to a second term on the right side of (Formula 3)) related to FOV movement, but may be individually displayed. In addition, in the layout diagram, the inspection point is shown, but the FOV may be shown. A target displayed in the layout diagram may be switched to the inspection point or the FOV by a display switch button 707.

FIG. 7B shows a screen change of FIG. 7A when the extraction condition is set by the user on the screen of FIG. 6A or FIG. 6B. For example, FIG. 7B indicates that a pattern 702 is a non-inspection pattern because the pattern 702 is not shaded. Accordingly, the user can confirm which pattern on the chip pattern 700 is actually excluded from the inspection targets according to the extraction condition. In addition, changes in the inspection time estimation 710 and the details 711 and 712 thereof are also shown. It is also possible to confirm the change in FOV by setting, as an FOV, the target to be displayed in the layout diagram.

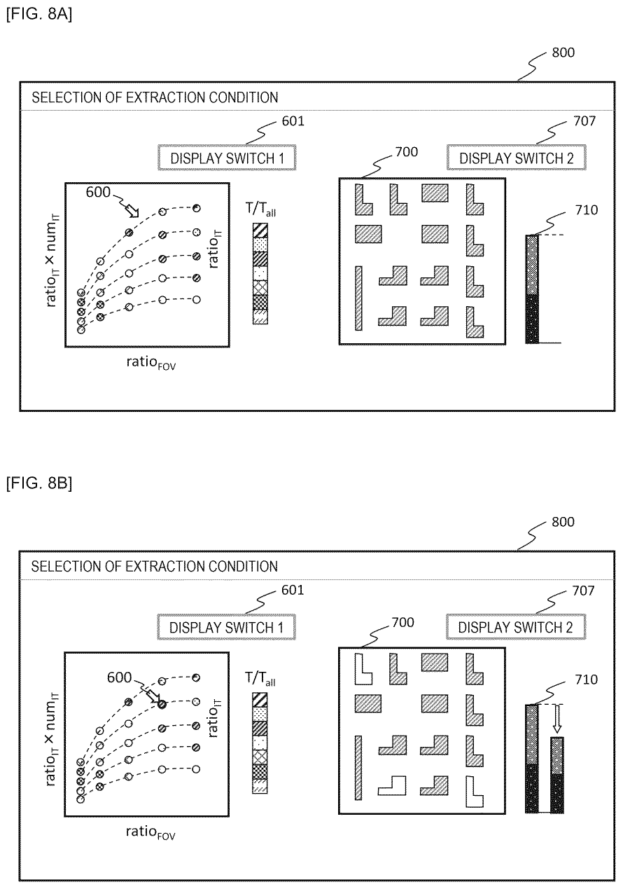

FIGS. 8A and B show examples of an extraction condition selection screen displayed on the display device 121 by the extraction condition setting unit 105. An extraction condition selection screen 800 presents extraction selection support information shown in FIGS. 6A and 6B and FIGS. 7A and 7B to the user side by side. FIG. 8A is a screen before the extraction condition is selected, and when the user selects a desired extraction condition by the pointer 600, a display content is updated to a state of FIG. 8B. As described above, when the extraction condition is selected, the FOV and the inspection point selected according to the extraction condition can be visually grasped, which helps the user to select an extraction condition.

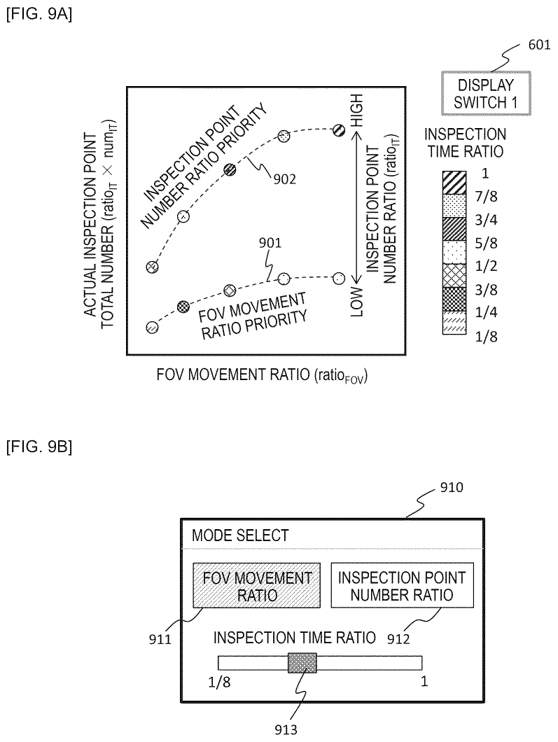

(Extraction Condition Setting Unit 105 (Modification)) In a modification, another example of the extraction condition selection screen displayed on the display device 121 by the extraction condition setting unit 105 is shown. FIG. 9A shows support information corresponding to FIG. 6A, and shows an example in which the extraction condition is reduced and, for example, the inspection point number ratio (ratio_{IT}) is fixed to two of 100% and 20%. As compared with FIG. 6A, since the extraction condition to be calculated is small, the time required for estimation of the inspection time by the inspection time estimation unit 102 can be significantly reduced.

An example of the extraction condition selection screen at this time is shown in FIG. 9B. A mode select screen 910 for selecting an extraction condition can select either a mode in which the FOV movement ratio (ratio_{FOV}) is prioritized or a mode in which the inspection point number ratio (ratio_{IT}) is prioritized, by pressing a select button 911 or a select button 912. The FOV movement ratio priority mode corresponds to a graph 901 shown in FIG. 9A, and the inspection point number ratio priority mode corresponds to a graph 902 shown in FIG. 9A. Under the selected mode condition, an inspection time ratio is selected by a slide bar 913. By using such a simplified extraction condition setting screen, it is possible to easily set the extraction condition without performing a selection error of the user or comparing complex conditions.

### (Inspection Data Extraction Unit 106)

When the extraction condition setting unit 105 sets any one of the conditions estimated by the inspection time estimation unit 102 as the extraction condition, the inspection data extraction unit 106 extracts, as an inspection point of the inspection data 112, an inspection point extracted from the grouping data 111 under the condition set as the extraction condition. The extracted inspection points are rearranged in the order of execution of the inspections, and become the inspection data 112.

### (Inspection Data Extraction Unit 106 (Modification))

A modification of the inspection data extraction unit 106 will be described. In the embodiment, an example is described in which the FOV and the inspection point to be inspected are extracted according to a certain rule. In this case, when there is a particular inspection point at which the user wants to perform an inspection without fail, the inspection point may be omitted from the inspection target. In order to avoid this, in the modification, an evaluation request list 113, which is a list of inspection points at which the user wants to perform inspections without fail, is registered in the storage unit 110. The inspection data extraction unit 106 merges the list of the inspection points registered in the evaluation request list 113 with a list of inspection points extracted according to the extraction condition set by the extraction condition setting unit 105. The list of the inspection points is rearranged in the order of execution of the inspection, and becomes the inspection data 112.

### Embodiment 2

In Embodiment 1, for an inspection sequence executed by the inspection control unit 108, after stage movement is performed by the stage mechanism 209, an FOV is defined by fine adjustment by image shift of the deflector 204. On the other hand, in Embodiment 2, the inspection sequence executed by the inspection control unit 108 is an inspection sequence in which after stage movement is performed by the stage mechanism 209, a plurality of FOVs are defined by the image shift of the deflector 204.

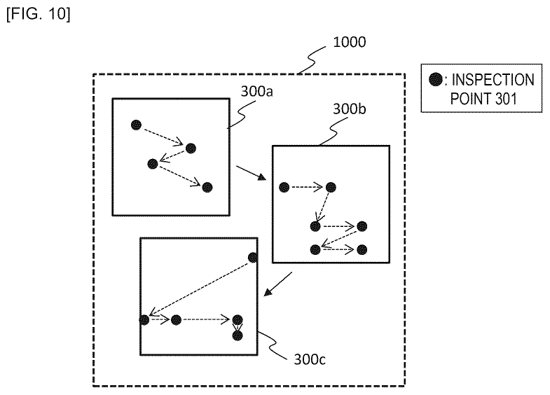

FIG. 10 schematically shows the inspection sequence according to Embodiment 2. Since the image shift deflects an electron beam to change the electron beam on a sample, a deflection amount has an upper limit. An inspection cover range 1000 indicates a range in which FOVs can be arranged by one time of stage movement and image shift. As described above, the inspection cover range 1000 defined by one time of stage movement includes a plurality of FOVs 300. In Embodiment 2, after the stage movement is performed by the stage mechanism 209, the inspection points 301 in an FOV 300a are inspected by moving to the FOV 300a by the image shift of the deflector 204. After that, movement to an FOV 300b by the image shift and the inspections of the inspection points 301 in the FOV 300b are performed, subsequently, movement to an FOV 300c by the image shift and the inspections of the inspection points 301 in the FOV 300c are performed, and the stage movement is performed by the stage mechanism 209 to the next stage position. By executing the inspections for all the inspection points listed in the inspection data 112 in a series of flows, the inspections are completed.

Therefore, unlike Embodiment 1, the number of times of FOV movement is different from the number of times of stage movement, and is equal to the number of times of image shift.

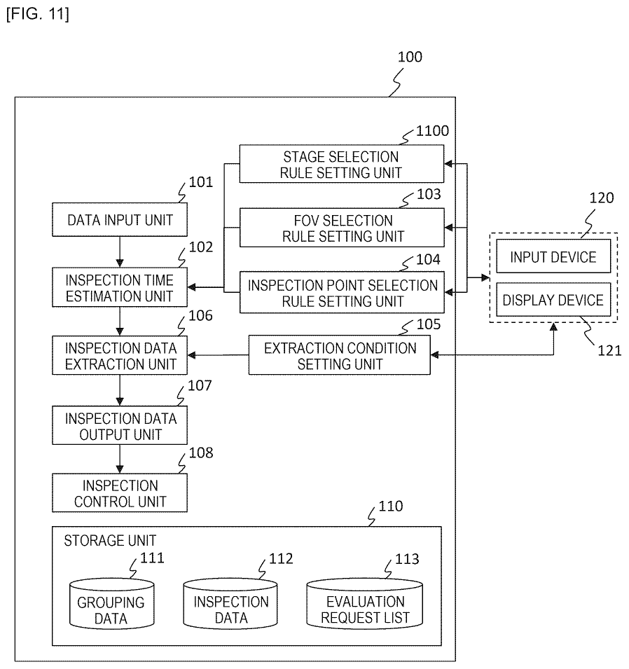

FIG. 11 is a functional block diagram of the control device 100 that determines an inspection flow of a wafer and executes an inspection by a charged particle beam device. The difference from Embodiment 1 is that the number of times of stage movement is added as a parameter for estimating an inspection time in the inspection time estimation unit 102, and a stage selection rule setting unit 1100 that sets a third rule (hereinafter referred to as a “stage selection rule”) for determining whether to perform or skip stage movement is added. Parts unique to Embodiment 2 will be mainly described below.

### (Inspection Time Estimation Unit 102)

The inspection time estimation unit 102 estimates an inspection time using the number of times of FOV movement, the number of inspection points, and the number of times of stage movement as parameters. A formula for estimating the inspection time is, for example, (Formula 4).

$$[ Formula 4 ]$$

$$T = {\sum }_{m = 1}^{{num}_{SM}} {x}_{m} * \{ {t}_{SM} * {a}_{m} + {\sum }_{n} {y}_{mn} * ( {t}_{IS} + {t}_{IT} * {ratio}_{IT} * {z}_{mn} ) \} \qquad ( 4 )$$

Here, T is a total inspection time, t_{SM}, t_{IS}, and t_{IT} are an average time taken for the stage movement by the stage mechanism 209, an average time taken for the image shift by the deflector 204, and an average time taken for the measurement of the inspection points, respectively. In addition, num_{SM} is a total number of times of stage movement defined in the grouping data 111. The grouping data 111 includes, in addition to information on the relationship between the inspection point of the wafer and the FOV in which the inspection point is inspected according to the inspection sequence of Embodiment 2, information on a relationship between the FOV and an inspection cover range (see FIG. 10) in which the FOV is included. num_{FOV} is a total number of FOVs defined in the grouping data 111. xₘ is a binary variable that becomes 1 or 0 depending on whether the m-th stage movement is performed or skipped, yₘₙ is a binary variable that becomes 1 or 0 depending on whether the n-th FOV movement (image shift) in the m-th stage movement is performed or skipped, and zₘₙ is the number of inspection points included in the n-th FOV in the m-th stage movement, and ratio_{IT} is a ratio of the number of inspection points to be actually inspected to the number of inspection points included in the FOV.

In addition, am is a flag variable determined by n-times of image shift included in the m-th stage movement, and is represented by (Formula 5).

$$[ Formula 5 ]$$

$${a}_{m} = \{ \begin{matrix}0 & ( {\sum }_{n} {y}_{mn} = 0 ) \\ 1 & ( {\sum }_{n} {y}_{mn} > 0 )\end{matrix} \qquad ( 5 )$$

Here, when (Formula 4) is modified using (Formula 6), (Formula 7) is obtained.

$$[ Formula 6 ]$$

$$\{ \begin{matrix}{ratio}_{SM} = \frac{{\sum }_{m = 1}^{{num}_{SM}} {x}_{m} * {a}_{m}}{{num}_{SM}} \\ {ratio}_{FOV} = \frac{{\sum }_{m = 1}^{{num}_{SM}} {x}_{m} * {\sum }_{n} {y}_{mn}}{{num}_{FOV}} \\ {num}_{IT} = {\sum }_{m = 1}^{{num}_{SM}} {x}_{m} * {\sum }_{n} {y}_{mn} * {z}_{mn}\end{matrix} \qquad ( 6 )$$

Here, ratio_{SM} is a stage movement ratio obtained by dividing the number of times of stage movement to be performed by the total number of times of stage movement num_{SM}. The ratio_{FOV} is an FOV movement ratio obtained by dividing the number of FOVs selected by performing FOV movement by the total number of FOVs num_{FOV}. In addition, num_{IT} is the total number of inspection points included in the FOV selected by performing FOV movement.

$$[ Formula 7 ]$$

$$T = ( {t}_{SM} * {ratio}_{SM} * {num}_{SM} ) + ( {t}_{IS} * {ratio}_{FOV} * {num}_{FOV} ) + ( {t}_{IT} * {ratio}_{IT} * {num}_{IT} ) \qquad ( 7 )$$

Here, t_{SM}, t_{IS}, and t_{IT} are values unique to the charged particle beam device to be inspected. (Formula 7) indicates that the total inspection time T is merely determined by the stage movement ratio ratio_{SM}, the FOV movement ratio ratio_{FOV}, and the inspection point number ratio ratio_{IT} even when the inspection cover range for performing the stage movement, the FOV for performing the FOV movement, and the inspection points to be actually inspected in the FOV are selected on any basis. Therefore, the stage selection rule, the FOV selection rule, and the inspection point selection rule for creating desired inspection coordinate data can be set without affecting the inspection time calculated by the inspection time estimation unit 102.

### (Extraction Condition Setting Unit 105)

In Embodiment 2, the inspection time estimation is calculated by a sum of a stage movement time required for the stage movement, an FOV movement time, and an inspection point measurement time. Therefore, the inspection time estimation 710 shown in FIGS. 7A and B may be displayed as a sum of the stage movement time (corresponding to a first term on the right side of (Formula 7)), the FOV movement time (corresponding to a second term on the right side of (Formula 7)), and the inspection point measurement time (corresponding to a third term on the right side of (Formula 7)).

### Embodiment 3

In the above-described embodiment, the wafer inspection management device 140 creates the grouping data 111, and transmits the grouping data 111 to the control device 100. On the other hand, in the embodiment, the control device 100 receives transmission of CAD data of a wafer to be inspected from the wafer inspection management device 140, and creates grouping data.

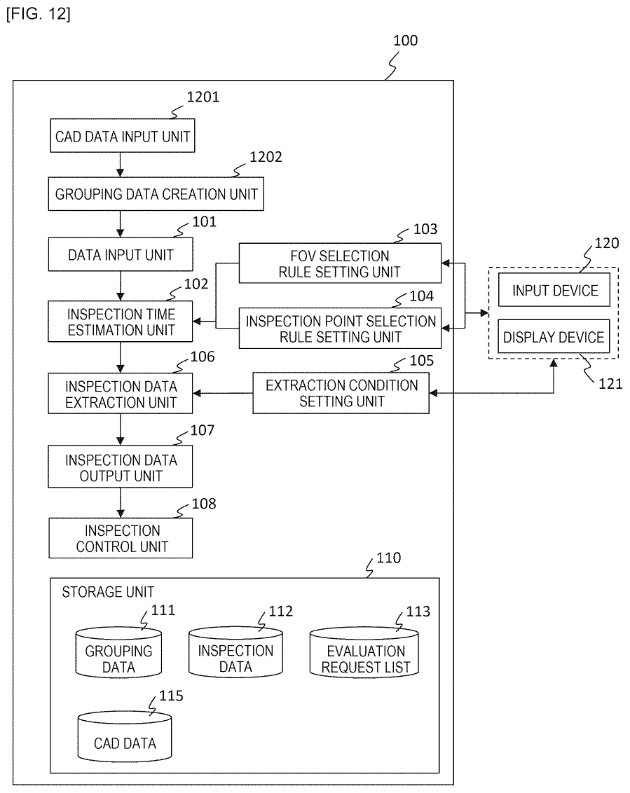

FIG. 12 is a functional block diagram of the control device 100 that determines an inspection flow of the wafer and executes an inspection by a charged particle beam device. The storage unit 110 stores CAD data 115 transmitted from the wafer inspection management device 140 to the control device 100. An inspection flow determination device according to Embodiment 3 includes a CAD data input unit 1201 to which the CAD data 115 is input, and a grouping data creation unit 1202 that creates the grouping data 111 based on the input CAD data 115. The created grouping data 111 may be directly input to the data input unit 101, or may be temporarily stored in the storage unit 110 and then received from the storage unit 110 to the data input unit 101.

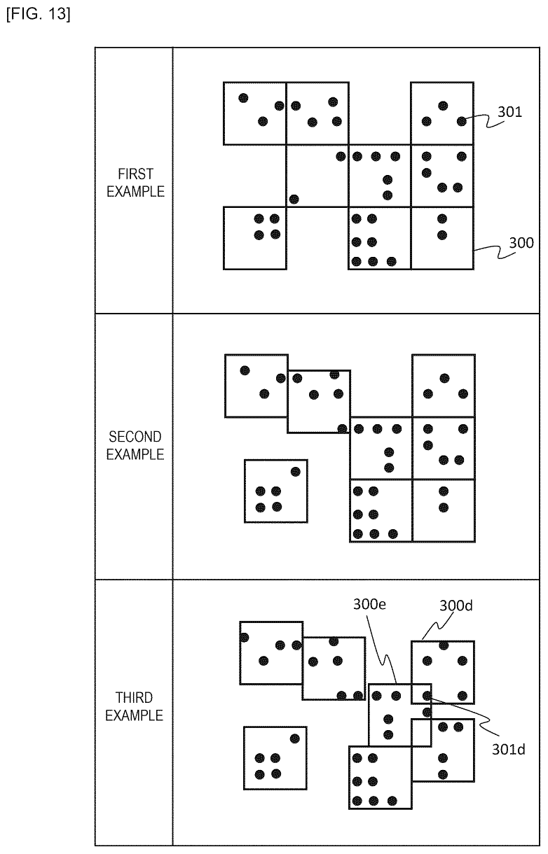

The grouping data creation unit 1202 extracts coordinate data of inspection points from the CAD data 115, and groups the extracted inspection points such that the extracted inspection points belong to at least one FOV. Grouping is performed according to an algorithm, and an example of the grouping is shown in FIG. 13. First to third examples each schematically show a state where the plurality of inspection points 301 in the same arrangement are grouped by the FOV 300. The first example is an example in which grouping is performed by a method of uniformly arranging FOVs having a constant size without a gap such that all inspection points are covered. The inspection points belonging to the same FOV are classified into the same group, and an FOV not including the inspection points is deleted. In the first example, the FOVs are arranged without overlapping. An inspection point necessarily belongs to one FOV. The second example is an example in which grouping is performed on all inspection points by a method of solving a set partitioning problem using FOVs having a constant size. In an optimum solution of the set partitioning problem, each inspection point is necessarily grouped into one FOV, and the number of FOVs is also minimized. Therefore, the number of FOVs may be reduced compared to the first example. The third example is an example in which grouping is performed on all inspection points by a method of solving a set covering problem using FOVs having a constant size. In the set covering problem, the inspection points are necessarily grouped into one or more FOVs. Therefore, like an inspection point 301d, there may be an inspection point that is grouped into a plurality of FOVs. In such a case, different results may be obtained when an FOV 300d and an FOV 300e are inspected. In order to avoid such a possibility, post-processing may be performed such that the inspection point 301d belongs to only one of the FOV 300d and the FOV 300e. In the optimization of the set covering problem, since overlapping of the FOVs is allowed, the number of FOVs may be further reduced as compared with the case of the second example.

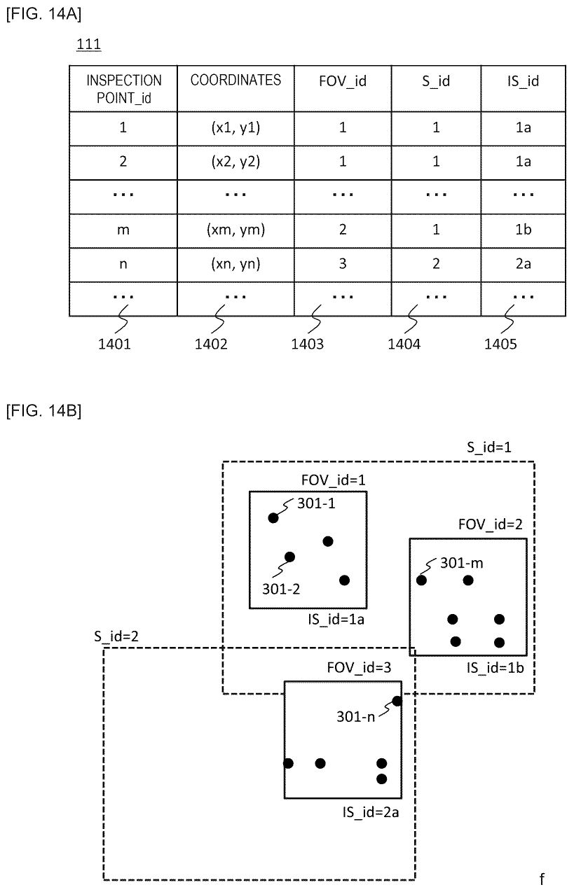

FIG. 14A shows a data structure example of the grouping data 111 created by the grouping data creation unit 1202. FIG. 14B shows an arrangement example of inspection points indicated by the grouping data 111 shown in FIG. 14A. A data structure of the grouping data in Embodiment 1 includes an inspection point ID 1401 that uniquely identifies an inspection point, coordinates 1402 that indicate coordinates of an inspection point, and an FOV ID 1403 that uniquely identifies an FOV. In addition to this, a data structure of the grouping data in Embodiment 2 may include a stage ID 1404 that uniquely identifies an inspection cover range, and an image shift ID 1405 that indicates image shift within the inspection cover range. As described above, since the FOVs are determined and the coordinates of the FOVs are determined, the stage ID 1404 and the image shift ID 1405 can be set by setting the inspection cover range such that the FOVs are grouped by the same method. The inspection data 112 corresponds to data in which inspection points to be actually inspected are extracted from the grouping data 111 based on the extraction condition and are rearranged in the order of executing the inspections.

### REFERENCE SIGNS LIST

100: control device
101: data input unit
102: inspection time estimation unit
103: FOV selection rule setting unit
104: inspection point selection rule setting unit
105: extraction condition setting unit
106: inspection data extraction unit
107: inspection data output unit
108: inspection control unit
110: storage unit
111: grouping data
112: inspection data
113: evaluation request list
115: CAD data
120: input device
121: display device
130: network
140: wafer inspection management device
151: processor (CPU)
152: memory
153: storage device
154: input I/F
155: output I/F
156: communication I/F
157: bus
200: electron microscope body
201: controller group
202: electron source
203: blanker
204: deflector
205: detector
207: electron lens
208: sample stage
209: stage mechanism
300: FOV
301: inspection point
400: selection rule setting screen
500: inspection boundary
600: pointer
601: display switch button
700: chip pattern
701: inspected pattern
702: pattern
707: display switch button
710: inspection time estimation
711: FOV movement time
712: inspection point measurement time
800: extraction condition selection screen
901, 902: graph
910: mode select screen
911, 912: select button
913: slide bar
1000: inspection cover range
1100: stage selection rule setting unit
1201: CAD data input unit
1202: grouping data creation unit
1401: inspection point ID
1402: coordinate
1403: FOV ID
1404: stage ID
1405: image shift ID

1. An inspection flow determination device comprising:
an inspection time estimation unit configured to estimate an inspection time required to inspect an inspection point extracted under a predetermined condition based on grouping data in which inspection points of a wafer to be inspected are grouped to belong to at least one field of view (FOV); and
an inspection data extraction unit configured to extract an inspection point, which is extracted using the condition selected based on the inspection time estimated by the inspection time estimation unit as an extraction condition, as an inspection point of inspection data indicating an inspection point where the wafer is actually inspected, wherein
the inspection time estimation unit extracts an inspection point from the grouping data based on an FOV selection rule for determining whether to perform or skip FOV movement using the number of times of FOV movement as a first parameter, and an inspection point selection rule for determining whether to actually inspect or skip an inspection point using the number of inspection points to be actually inspected in the FOV as a second parameter.

2. The inspection flow determination device according to claim 1, wherein
the FOV selection rule rearranges FOVs included in the grouping data in ascending order or descending order according to the number of inspection points in the FOVs, and determines whether to perform or skip the FOV movement based on a set first threshold, and
the first threshold is set for an FOV movement ratio which is a ratio of the number of times of FOV movement as the first parameter to the total number of times of FOV movement required to inspect all inspection points included in the grouping data.

3. The inspection flow determination device according to claim 1, wherein
the inspection point selection rule rearranges inspection points included in an FOV in the grouping data in ascending order or descending order according to an inspection point distance, and determines whether to actually inspect or skip the inspection points based on a set second threshold,
the inspection point distance is defined as either a distance from an FOV center position to an inspection point in a first direction or a distance in a second direction orthogonal to the first direction, whichever is larger, and
the second threshold is set for an inspection point number ratio which is a ratio of the number of inspection points as the second parameter to the number of inspection points included in the FOV in the grouping data.

4. The inspection flow determination device according to claim 1, wherein
the inspection data extraction unit merges inspection points registered in a list of predetermined inspection points with the inspection points extracted under the extraction condition, and extracts the merged inspection points as the inspection point of the inspection data.

5. The inspection flow determination device according to claim 1, further comprising:
a grouping data creation unit configured to extract coordinate data of inspection points from CAD data of the wafer to be inspected, and create the grouping data by grouping the extracted inspection points such that the extracted inspection points belong to at least one FOV.

6. The inspection flow determination device according to claim 5, wherein
the grouping data creation unit groups, by a method of uniformly arranging FOVs having a constant size without a gap, all inspection points extracted from the CAD data such that all the inspection points are covered, groups, by solving a set partitioning problem using the FOVs having the constant size, all the inspection points extracted from the CAD data, or groups, by solving a set covering problem using the FOVs having the constant size, all the inspection points extracted from the CAD data.

7. The inspection flow determination device according to claim 1, wherein
the FOV movement is performed by stage movement due to a stage mechanism for driving a sample stage on which the wafer is placed and image shift due to a deflector for deflecting an electron beam emitted to the wafer,
the inspection time estimation unit calculates the inspection time as a sum of an FOV movement time and an inspection point measurement time,
the FOV movement time is calculated as a product of the total number of times of FOV movement required to inspect all inspection points included in the grouping data, an FOV movement ratio which is a ratio of the number of times of FOV movement as the first parameter to the total number of times of FOV movement, and an average time required for one time of FOV movement, and
the inspection point measurement time is calculated as a product of the number of all inspection points included in a selection FOV selected according to the FOV selection rule, the inspection point number ratio which is a ratio of the number of inspection points as the second parameter to the number of inspection points included in the selection FOV in the grouping data, and an average time required for one time of inspection point measurement.

8. The inspection flow determination device according to claim 1, wherein
the FOV movement is performed by stage movement due to a stage mechanism for driving a sample stage on which the wafer is placed and image shift due to a deflector for deflecting an electron beam, which is emitted to the wafer, to any FOV among a plurality of FOVs included in an inspection cover range defined by the stage movement, and
the inspection time estimation unit further extracts an inspection point from the grouping data based on a stage selection rule for determining whether to perform or skip the stage movement by using the number of times of stage movement as a third parameter.

9. The inspection flow determination device according to claim 8, wherein
the inspection time estimation unit calculates the inspection time as a sum of a stage movement time, an FOV movement time, and an inspection point measurement time,
the stage movement time is calculated as a product of the total number of times of stage movement required to inspect all inspection points included in the grouping data, a stage movement ratio which is a ratio of the number of times of stage movement as the third parameter to the total number of times of stage movement, and an average time required for one time of stage movement,
the FOV movement time is calculated as a product of the total number of times of FOV movement required to inspect all the inspection points included in the grouping data, an FOV movement ratio which is a ratio of the number of times of FOV movement as the first parameter to the total number of times of FOV movement, and an average time required for one time of FOV movement, and
the inspection point measurement time is calculated as a product of the number of all inspection points included in a selection FOV selected according to the FOV selection rule, the inspection point number ratio which is a ratio of the number of inspection points as the second parameter to the number of inspection points included in the selection FOV in the grouping data, and an average time required for one time of inspection point measurement.

10. A charged particle beam device comprising:
a charged particle optical system including a charged particle source;
a stage mechanism system on which the wafer irradiated with a charged particle beam from the charged particle source is placed;
a controller group configured to control the charged particle optical system and the stage mechanism system;
the inspection flow determination device comprising
an inspection time estimation unit configured to estimate an inspection time required to inspect an inspection point extracted under a predetermined condition based on grouping data in which inspection points of a wafer to be inspected are grouped to belong to at least one field of view (FOV); and
an inspection data extraction unit configured to extract an inspection point, which is extracted using the condition selected based on the inspection time estimated by the inspection time estimation unit as an extraction condition, as an inspection point of inspection data indicating an inspection point where the wafer is actually inspected, wherein
the inspection time estimation unit extracts an inspection point from the grouping data based on an FOV selection rule for determining whether to perform or skip FOV movement using the number of times of FOV movement as a first parameter, and an inspection point selection rule for determining whether to actually inspect or skip an inspection point using the number of inspection points to be actually inspected in the FOV as a second parameter; and
an inspection control unit configured to control the controller group to inspect an inspection point of the wafer according to the inspection data.

11. The charged particle beam device according to claim 10, wherein
the inspection is dimension measurement at the inspection point or electric characteristic measurement at the inspection point.

12. A program for causing a computer to implement:
an inspection time estimation function of estimating an inspection time required to inspect an inspection point extracted under a predetermined condition based on grouping data in which inspection points of a wafer to be inspected are grouped to belong to at least one field of view (FOV); and
an inspection data extraction function of extracting an inspection point, which is extracted using the condition selected based on the inspection time estimated by the inspection time estimation unit as an extraction condition, as an inspection point of inspection data indicating an inspection point where the wafer is actually inspected, wherein
the inspection time estimation function extracts an inspection point from the grouping data based on an FOV selection rule for determining whether to perform or skip FOV movement using the number of times of FOV movement as a first parameter, and an inspection point selection rule for determining whether to actually inspect or skip an inspection point using the number of inspection points to be actually inspected in the FOV as a second parameter.

13. The program according to claim 12 for causing a computer to further implement:
a grouping data creation function of extracting coordinate data of inspection points from CAD data of the wafer to be inspected, and creating the grouping data by grouping the extracted inspection points such that the extracted inspection points belong to at least one FOV.

14. An inspection flow determination device comprising:
an inspection time estimation unit configured to estimate an inspection time required to inspect an inspection point extracted under a predetermined condition based on grouping data in which inspection points of a wafer to be inspected are grouped to belong to at least one field of view (FOV);
an extraction condition setting unit; and
an inspection data extraction unit configured to extract an inspection point extracted under an extraction condition set by the extraction condition setting unit as an inspection point of inspection data indicating an inspection point where the wafer is actually inspected, wherein
the inspection time estimation unit extracts an inspection point from the grouping data based on an FOV selection rule for determining whether to perform or skip FOV movement using the number of times of FOV movement as a first parameter, and an inspection point selection rule for determining whether to actually inspect or skip an inspection point using the number of inspection points to be actually inspected in the FOV as a second parameter,
the inspection time estimation unit estimates an inspection time under a plurality of the predetermined conditions in which the first parameter and/or the second parameter are different, and
the extraction condition setting unit displays, on a display device, first information based on the number of times of FOV movement as the first parameter, second information based on the number of inspection points as the second parameter, and third information based on the inspection time estimated by the inspection time estimation unit.

15. The inspection flow determination device according to claim 14, wherein
the extraction condition setting unit is capable of selecting any one of the plurality of predetermined conditions as the extraction condition.

16. The inspection flow determination device according to claim 14, wherein
the inspection time estimation unit estimates an inspection time under the plurality of predetermined conditions corresponding to a first parameter priority mode in which the first parameter is prioritized and the plurality of predetermined conditions corresponding to a second parameter priority mode in which the second parameter is prioritized, and
the extraction condition setting unit displays the first information, the second information, and the third information on the display device for each of the first parameter priority mode and the second parameter priority mode.

17. The inspection flow determination device according to claim 16, wherein
the extraction condition setting unit is capable of selecting one of the first parameter priority mode and the second parameter priority mode as the extraction condition.
